(19) United States
(12) Patent Application Publication
(10) Pub. No.: US 2006/0159847 A1
(43) Pub. Date: Jul. 20, 2006

(54) Method and apparatus for low temperature dielectric deposition using monomolecular precursors

(76) Inventors: Cole Porter, San Jose, CA (US); Karl Williams, Half Moon Bay, CA (US); Helmuth Treichel, Milpitas, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/239,880

(22) Filed: Sep. 30, 2005

Related U.S. Application Data
(60) Provisional application No. 60/615,135, filed on Sep. 30, 2004.

(51) Int. Cl. C23C 16/00

(52) U.S. Cl. 427/248.1; 118/715

(57) ABSTRACT

In one aspect, the present invention provides a method and apparatus configured to form dielectric films or layers at low temperature. In one embodiment dielectric films such as silicon nitride (SixNy) and silicon dioxide (SiO₂) are deposited at temperatures equal to or below 550° C. In a further aspect of the present invention, a method and apparatus configured to provide cross flow injection of reactant gases is provided. In one embodiment, reactant gasses (such as a monomolecular precursor and NH₃) flow into vertically positioned adjustable injectors that mix reactants prior to injection into the wafer region.

FIELD OF THE INVENTION

The present invention relates generally to semiconductor processing and manufacturing apparatus. More specifically, the invention relates to methods and apparatus for forming dielectric films or layers at low temperature.

BACKGROUND OF THE INVENTION

The deposition of silicon nitride and/or silicon oxide films on the surface of semiconductor substrates using low temperature processing, particularly for SiN films, has recently received a great deal of attention in the semiconductor industry. Silicon nitride films are used extensively in the semiconductor industry for device passivation, mechanical protection, capping layers, contaminant barriers, on-chip capacitor dielectrics, interlayer dielectrics, freestanding membranes, and the like.

While the past ten or more years of CMOS junction development have been addressed primarily through variations to conventional implant-and-anneal-in-Si techniques, the next advances in the industry will likely involve modifications to both the material systems and their manner of introduction. Complicating these changes is the expectation that the channel and the gate stack material systems will simultaneously be undergoing revolutionary change, with a likely need to avoid interdiffusion or recrystallization, and thus can be expected to put an upper limit on the thermal budget allowed in the CMOS front end processing.

Accordingly, further developments are needed.

### BRIEF SUMMARY OF THE INVENTION

In general, the present invention provides methods and apparatus for forming dielectric films.

In one aspect, the present invention provides a method and apparatus configured to form dielectric films or layers at low temperature. In one embodiment dielectric films such as silicon nitride (SixNy) and silicon dioxide (SiO₂) are deposited at temperatures equal to or below 550° C.

In another aspect of the present invention dielectric films are deposited using monomolecular precursors having one or more Si—N linkages or bonds. In one embodiment, monomolecular precursors are provided of the formula:
N(SiR₃)₃

Where R=H, alkyl, aryl, or amido.

In one embodiment the monomolecular precursor is trisilylamine (N(SiH₃)₃). In an alternative embodiment, monomolecular precursors are comprised of cyclic Si—N compounds. Examples of cyclic Si—N compounds include, but are not limited to, cyclic polyamides or polyamines (C replaced by Si).

In yet another aspect of the present invention, a method and apparatus configured to provide cross flow injection of reactant gases is provided. In one embodiment, reactant gasses (such as a monomolecular precursor and NH₃) flow into vertically positioned adjustable injectors that mix reactants prior to injection into the wafer region. Gases exit the injectors through multiple holes that are positioned throughout the injectors to promote flow uniformity and velocity axially in the chamber. This is found to promote deposition of good quality films, and of particular advantage allows for carrying out the process at low temperatures.

In a further aspect of the invention, an apparatus is provided, comprising: a processing chamber, a wafer carrier positioned in the chamber and supporting a plurality of substrates; and an adjustable injector tube comprising a plurality of vertically positioned injectors along the vertical length of the injector tube. The vertically positioned injectors are configured to convey gases across the surface of said plurality of substrates.

BRIEF DESCRIPTION OF THE DRAWINGS

Advantages and embodiments of the present invention will become apparent upon reading the following detailed description and upon reference to the following figures, in which:

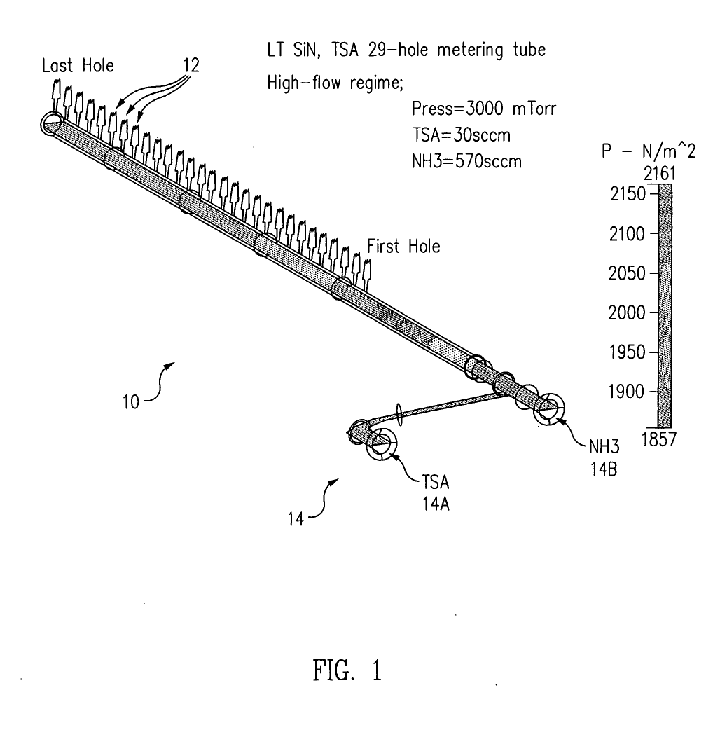

FIG. 1 is an elevated simplified view of an adjustable injector tube in accordance with one embodiment of the present invention;

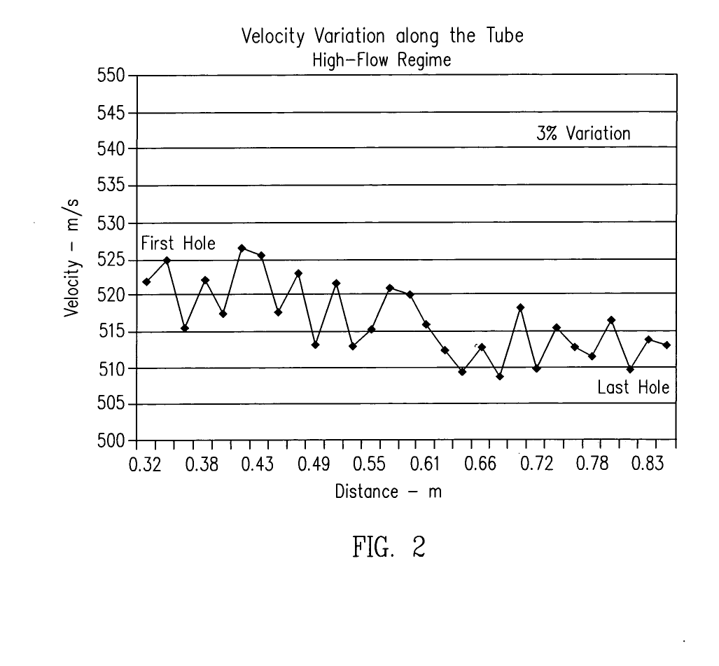

FIG. 2 is graph illustrating gas velocity variation along the injector tube;

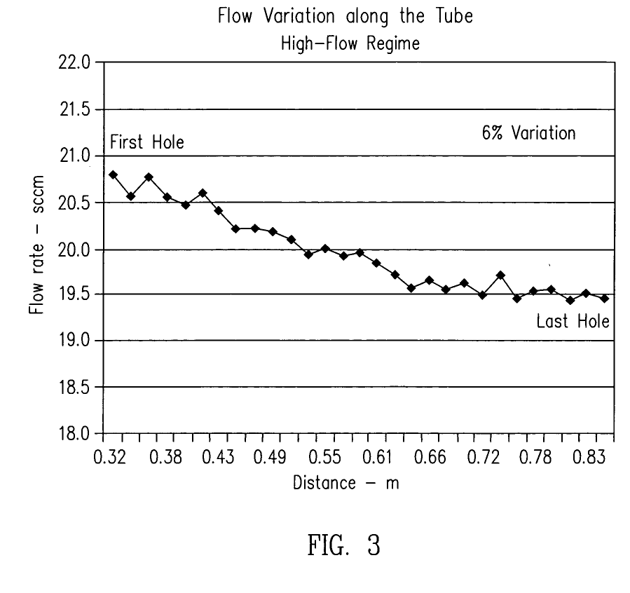

FIG. 3 is a graph showing gas flow rate variation along the injector tube;

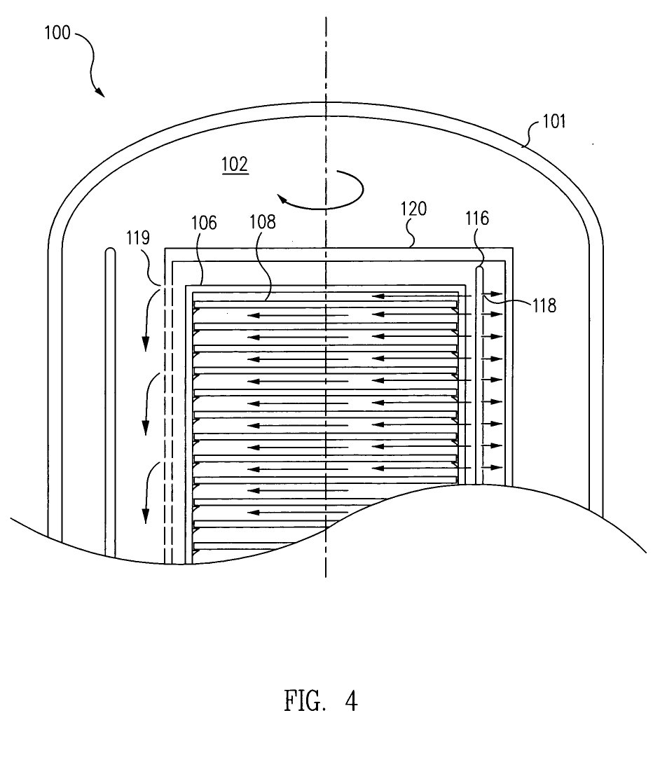

FIG. 4 is a cross-sectional view of a portion of a thermal processing apparatus that may be employed according to one embodiment of the present invention;

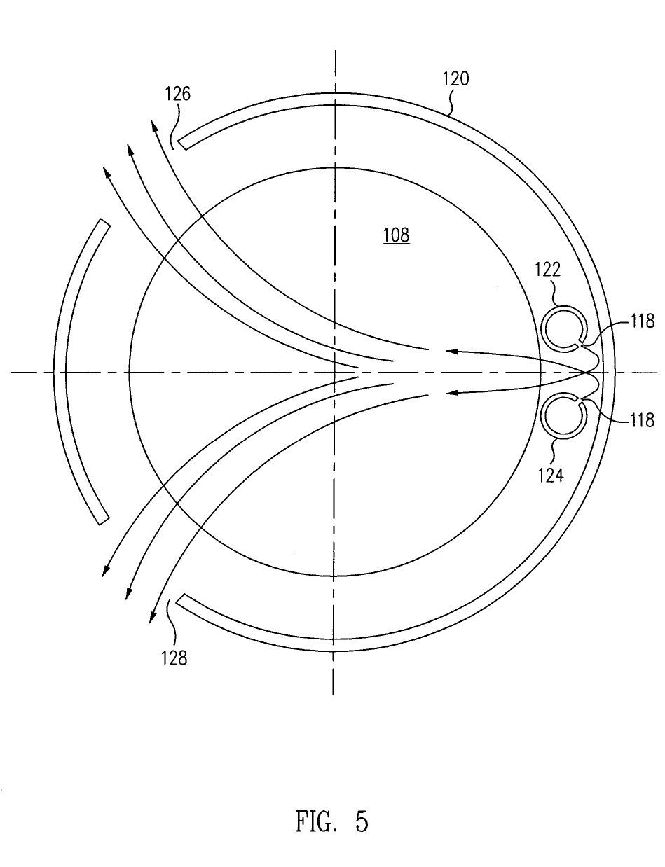

FIG. 5 is a top plan view of a portion of the thermal processing apparatus of FIG. 4 showing gas flow from injections across a wafer and to exhaust ports according to some embodiments of the present invention;

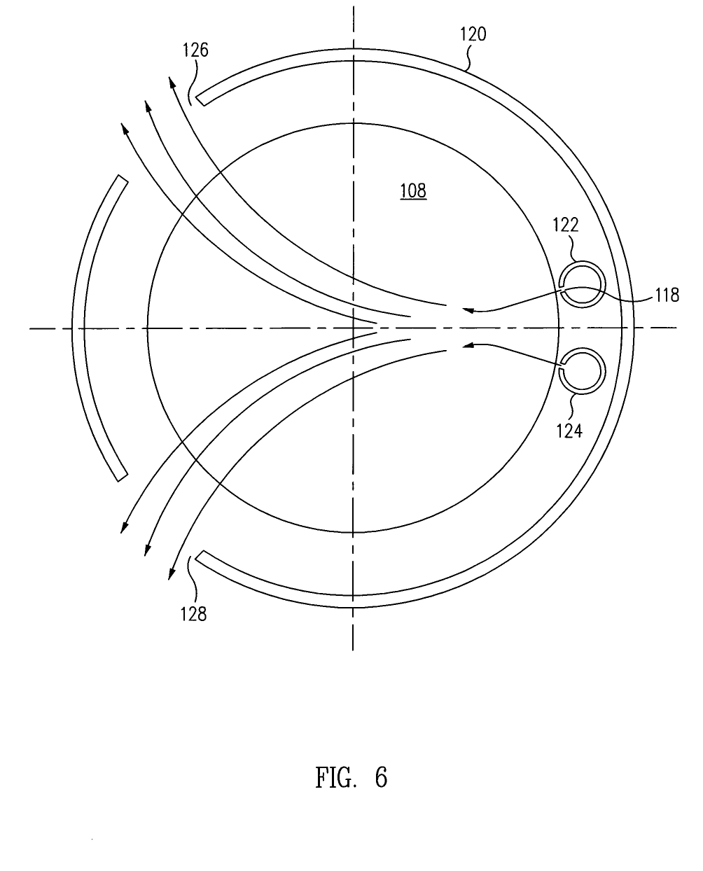

FIG. 6 is a top plan view of a portion of the thermal processing apparatus of FIG. 4 showing gas flow across a wafer according to a different injector configuration; and

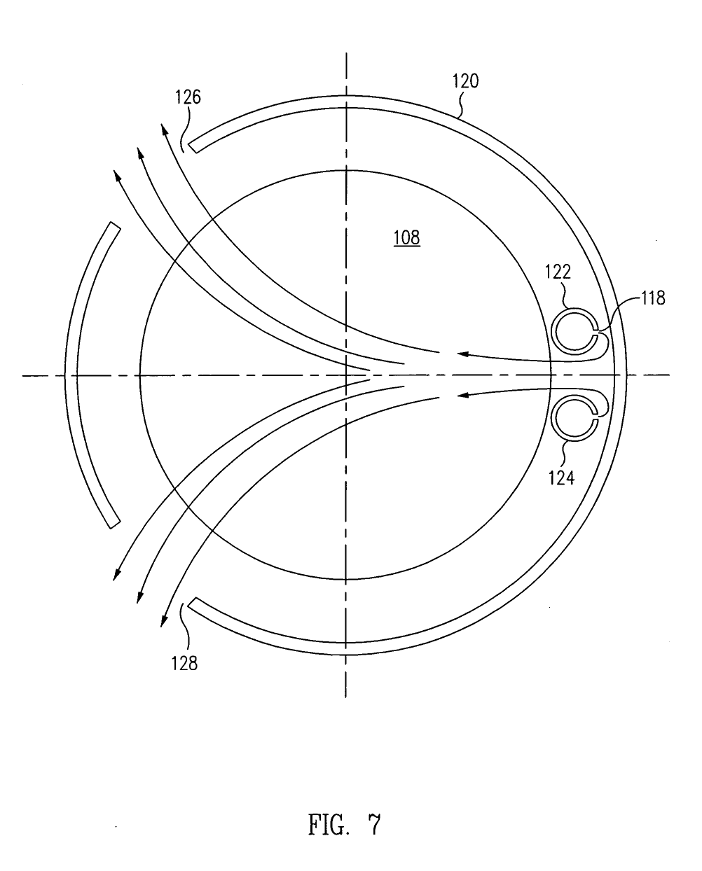

FIG. 7 is a top plan view of a portion of the thermal processing apparatus of FIG. 4 showing gas flow across a wafer according to another different injector configuration

### DETAILED DESCRIPTION OF THE INVENTION

In one aspect, the present invention provides a method and apparatus configured to form dielectric films or layers at low temperature. In one embodiment dielectric films such as silicon nitride (SixNy) and silicon dioxide (SiO₂) are deposited at wafer temperatures equal to or below 550° C.

In another aspect of the present invention dielectric films are deposited using monomolecular precursors having one or more Si—N linkages or bonds. In one embodiment, monomolecular precursors are provided of the formula:
N(SiR₃)₃

Where R=H, alkyl, aryl, or amido.

In one embodiment the monomolecular precursor is trisilylamine (N(SiH₃)₃). In an alternative embodiment, monomolecular precursors are comprised of cyclic Si—N compounds. Examples of cyclic Si—N compounds include, but are not limited to, cyclic polyamides or polyamines (Carbon replaced by Silicon). The silicon precursors replace silane, dichlorosilane or other carbon and/or chlorine containing precursors, which typically are used as the source of silicon for these applications.

In a further aspect of the present invention, a method and apparatus configured to provide cross flow injection of reactant gases is provided. In one embodiment, reactant gasses (such as a monomolecular precursor and NH₃) flow into vertically positioned adjustable injectors that mix reactants prior to injection into the wafer region. Gases exit the injectors through multiple holes that are positioned throughout the injectors to promote flow uniformity and velocity axially in the chamber. This is found to promote deposition of good quality films, and of particular advantage allows for carrying out the process at low temperatures.

Referring to FIG. 1, one embodiment of an injection tube 10 which may be utilized for cross flow injection according to the present invention is shown. In this embodiment, the adjustable injection tube 10 includes a plurality of holes or injectors 12 along its substantial length. In one aspect of the present invention, cross flow injection of the reactant gases is provided. Reactant gasses, preferably a monomolecular precursor and NH₃ in the instance a silicon nitride film is to be formed, flow into vertically positioned adjustable injectors that mix reactants prior to injection into the wafer region. The injectors are configured to mix the two reactant gasses inside the process chamber and inside an injector tube 10 as shown in FIG. 1. In one embodiment, at one end of the injector tube 10 are one or more gas delivery ports 14. In the exemplary embodiment shown in FIG. 1, two gas delivery ports 14A and 14B are shown. Flow control systems (not shown) may be used to control the flow of reactants through the respective delivery ports to the injector tube 10. While two gas delivery ports are shown, those of ordinary skill in the art will recognize that additional gas delivery ports may be used as needed to supply additional gases to the injector tube 10. Of significant advantage, the injector tube 10 promotes mixing of gases in the tube 10. This mixing of the reactants prior to exiting the multiple injectors 12 enables more uniform film composition across the wafer surface.

Additionally, this premixing of the gasses helps prevent deposition of high silicon concentration films within the injector surface that may have a significantly different thermal expansion coefficient than Si₃N₄ which would cause flaking of the film from the injector's inner walls contributing to particle generation and defects on the wafer surface. Mixing of the gasses inside the injector tube 10 in a zone of the chamber that is at a considerably lower temperature than the molecules activation energy promotes a conformal film composition deposition through the entire process chamber and injector surfaces. A conformal film composition is desired in many applications, for example when performing in-situ cleaning due to etch rate variations of varying films using NF₃ or Fluorine compounds.

Gases exit the injectors through multiple holes or injectors 12 that are positioned throughout the adjustable injector tube 10 to promote flow uniformity and velocity axially in the chamber. In some embodiments, gasses exit the injector holes, deflect from the chamber walls to optimize gas flow uniformity flow horizontally and parallel to the surface of the wafers and exit the chamber opposite the injection side of the chamber. Exhaust slots are positioned opposite the injectors in the wall of the chamber. The exhaust slots are preferably positioned through the chamber to promote flow uniformity and velocity axially in the chamber. This cross flow direction of the reactant gasses enables uniform deposition of the film within the wafer (radial) and wafer to wafer (axial) direction. By creating a cross flow gas pattern, depletion effects are overcome that are experienced in reactors which have only one injection point localized in the chamber. Abundance of available reactants is created in all locations of the reaction chamber. Gas velocities and density are adequate to establish uniform distribution of reactants in the radial direction across the wafer's surfaces. A uniform axial gas distribution is established with the injector hole size and positions creating a uniform pressure inside the injector tube, which equates to a uniform flow rate and velocity exiting the injector holes across the entire hole pattern of the injector tube.

In one embodiment, the process chamber is configured in such a manner as to practice the inventive method on a plurality of substrates, typically numbering up to 200 substrates or wafers stacked in a wafer boat. In one example a batch process chamber contains between 50 and 150 wafers. A “mini-batch” reactor may also be employed wherein a batch of substrates numbering between 1 and 50 are housed in a process chamber. Alternatively the mini-batch process chamber is configured to process between 1 and 25 substrates. One example of a mini-batch system is described in PCT patent application Ser. No. PCT/US03/21575 entitled Thermal Processing System and Configurable Vertical Chamber, the entire disclosure of which is incorporated by reference herein. While a number of examples are described it should be understood that the present invention may be carried out in a variety of chambers.

Preferably, injection of the reactant gases is configured such that wafers at the top of the wafer boat are in the abundance reaction regime or in a reduced starvation regime. Injection preferably provides a means to transfer the precursors past the lower ½ of the wafer load and increase partial pressures of available reactants at the upper ½ of the wafer load.

Using a monomolecular precursor in conjunction with the above described cross flow apparatus enables higher deposition rates due to a higher rate of gas transport to the reaction surface. This technique overcomes gas transport issues placing enough reaction constituents at the wafer surface thereby moving reaction kinetics to a surface limited regime where film uniformities are optimized and deposition rates are maximized.

FIGS. 2 and 3 are graphs illustrating gas velocity and flow modeling that demonstrates uniform velocity (3% variation) and flow (6% variation) using fixed gas flow, hole size and hole quantity according to exemplary embodiments of the present invention. Variations in hole size can be used to accommodate large variations in gas flow.

In another aspect, the present invention provides additional apparatus embodiments that provide for cross-flow delivery of the monomolecular precursors at low temperature to form a monomolecular film. FIG. 4 is a simplified cross-sectional partial view of one embodiment of an apparatus 100 for processing a batch of semiconductor wafers. Generally, the apparatus 100 comprises a vessel 101 that encloses a volume to form a process chamber 102. The process chamber houses a carrier or wafer boat 106. The wafer boat 106 supports a plurality or batch of wafers 108. A heat source or furnace (not shown) is provided for heating the wafers to a desired temperature. A liner 120 may be positioned between the wafer boat 106 and the vessel 101. The liner 120 promotes increased concentration of reactant gases near the wafers 108. Typically, the wafer boat 106 is rotated during processing by a rotating mechanism (not shown).

Of particular advantage, embodiments of the present invention provide for depositing dielectric films or layers at low temperature and by delivering the reactant gases to the wafers in a cross flow manner. Referring again to FIG. 4, one or more injector tubes 116 are provided for delivering gases in a cross flow manner. Injector tubes 116 generally comprise a plurality of injectors or holes 118 formed along the substantial length of the injector tube 116. Gases are introduced through the injectors 118 on one side of the wafers 108 and flow across the surface of the wafers in a cross flow manner generally shown by the direction of the arrows in FIG. 4 and exit at exhaust ports or slots 119 positioned at an opposite side of the injectors 118. Exhaust ports 119 may be formed in the liner 120. Gases exit the exhaust ports 119 and are then exhausted from the chamber through one or more exhaust lines (not shown).

In some embodiments the gas is initially directed away from the wafers 108 toward the liner 120 or chamber wall to promote further mixing of the reactant gas before it reaches the wafer. In other embodiments, gases are initially directed toward the wafers 108. The injector tube 116 and thus the injectors 118 are adjustable, so that any desired orientation may be achieved, i.e. the gases may exit the injectors throughout a rotation of 360 degrees.

In other embodiments, two or more injector tubes 116 may be employed. In this embodiment, separate gases are delivered through separate injector tubes, and the gases mix in the chamber once the gases exit the injectors 118. Alternatively, one or more of the injector tubes 116 may convey mixed gases as shown in FIG. 1, and then further mixing occurs when gases from each of the two injector tubes 116 exit the injectors 118. This provides tremendous flexibility and adaptability making the invention suitable for many processes.

Specifically, referring to FIG. 5, a top plan view of a portion of the thermal processing apparatus of FIG. 4 showing gas flow from two injector tubes 122 and 124, across a wafer 108, and to multiple exhaust ports 126 and 128 is illustrated. The process gas or vapor is delivered via injectors and is initially directed away from the wafers 108 and toward the liner 120 to promote mixing of the gases or vapor before it reaches the wafers. This configuration of injectors is particularly useful for processes or recipes in which different reactant gases are introduced from each of the injector tubes 122 and 124, for example to form a multi-component film or layer. It should also be noted that the dimensions of the injectors, and the exhaust slots relative to the wafer 108 and the chamber liner 120 have been exaggerated to more clearly illustrate the gas flow from the injectors to the exhaust slots.

As described above, the injector tubes are adjustable and may be rotated as desired. FIGS. 6 and 7 are top plan views of a portion of the thermal processing apparatus of FIG. 4 showing gas flow according to different configurations of the adjustable injector tubes 122 and 124. While specific configurations have been shown, it is to be understood that any suitable rotational configuration may be employed. Additionally, while two exhaust slots are generally shown, one exhaust slot may be employed, or more than two may also be employed, the only criteria being that the exhaust slots are positioned away from the injectors in order to promote flow of the gases across the wafer surface.

Exemplary embodiments have been described with reference to specific configurations. The foregoing description of specific embodiments and examples of the invention have been presented for the purpose of illustration and description, and although the invention has been illustrated by certain of the preceding examples, it is not to be construed as being limited thereby.

What is claimed:

1. A method of forming a dielectric film, comprising the steps of:
conveying one or more monomolecular precursors having one or more Si—N linkages; and
depositing a dielectric film at a wafer temperature of equal to or below 550° C.

2. The method of claim 1 wherein said one or more monomolecular precursors is comprised of the formula:
N(SiR₃)₃
where R =H, alkyl, aryl, or amido.

3. The method of claim 1 wherein said one or more monomolecular precursors is one or more cyclic Si—N compounds.

4. A method of forming a dielectric film, comprising the steps of:
conveying one or more reactant gases into one or more vertically positioned adjustable injector tubes, said injector tubes being configured to mix the reactant gases prior to injection of the gases into a chamber; and
depositing a dielectric film at a wafer temperature of equal to or below 550° C.

5. The method of claim 4 wherein the reactant gases exit the injector tube through multiple injectors that are positioned throughout the length of the injector tube to promote flow uniformity and velocity axially in the chamber.

6. The method of claim 4 wherein said reactant gases are mixed in said injectors at a temperature lower than the reactant gas molecules activation energy.

7. The method of claim 4 where said chamber is configured to house up to 200 wafers or substrates.

8. The method of claim 4 where said chamber is configured to house between 1 to 50 wafers or substrates.

9. The method of claim 4 where said chamber is configured to house between 50 and 150 wafers.

10. An apparatus, comprising:
a processing chamber;
a wafer carrier positioned in said chamber and supporting a plurality of substrates; and
an adjustable injector tube comprising a plurality of vertically positioned injectors along the vertical length of the injector tube, said vertically positioned injectors configured to convey gases across the surface of said plurality of substrates.

11. The apparatus of claim 10 wherein said adjustable injector tube may be rotated 360 degrees.

12. The apparatus of claim 10 further comprising a plurality of exhaust slots positioned opposite of said vertically positioned injectors.
